(19) United States
(12) Patent Application Publication
(10) Pub. No.: US 2026/0323933 A1
(43) Pub. Date: Oct. 15, 2026

(54) SEMICONDUCTOR DEVICE

(71) Applicant: Fujian Jinhua Integrated Circuit Co., Ltd., Fujian (CN)

(72) Inventors: Yirong XU, Fujian (CN); Janbo ZHANG, Fujian (CN); Youchang WANG, Fujian (CN); Yanzhen ZHOU, Fujian (CN)

(73) Assignee: Fujian Jinhua Integrated Circuit Co., Ltd., Fujian (CN)

(21) Appl. No.: 19/643,791

(22) Filed: Apr. 9, 2026

(30) Foreign Application Priority Data
Apr. 10, 2025 (CN) 202510449450.7

(51) Int. Cl. H10B 12/00

(52) U.S. Cl. CPC H10B 12/50; H10B 12/09; H10B 12/482

(57) ABSTRACT

The present application provides a semiconductor device, applied in the field of semiconductor technology. In the present application, the semiconductor device may include a plurality of dummy bit lines having different widths and intervals in the horizontal direction, so as to propose a new structure and achieve the purpose of improving the reliability and performance of the semiconductor device.

### CROSS-REFERENCE TO RELATED APPLICATION

This application claims priority to Chinese Patent Application No. 202510449450.7, filed on Apr. 10, 2025, which is hereby incorporated by reference in its entirety.

### BACKGROUND

### TECHNICAL FIELD

The present application relates to semiconductor technical field, and particularly relates to a semiconductor device.

### DESCRIPTION OF RELATED ART

Dynamic random access memory (DRAM) is a type of volatile memory, including an array area composed of a plurality of memory cells and a periphery region composed of a control circuit. Each memory cell includes a transistor electrically connected to a capacitor; the transistor controls storing or releasing charges in the capacitor to achieve data storage. The control circuit can locate, through word lines (WL) and bit lines (BL) that span the array area and are electrically connected to each memory cell, each memory cell to control data access.

### SUMMARY

A purpose of the present application is to provide a semiconductor device to improve reliability and performance of the semiconductor device.

To solve the above technical problem, the first embodiment of the present application provides a semiconductor device including:
substrate;
a plurality of shallow trench isolations, arranged in the substrate and spaced apart from each other; the shallow trench isolations define a plurality of active areas, including a plurality of first active areas having a first width and at least one second active area having a second width; the at least one second active area is arranged on an outer side of all the first active areas, and the first width is smaller than the second width;
an insulating layer, located on the substrate and the shallow trench isolations;
a plurality of bit lines, arranged on the substrate along a horizontal direction and spaced apart from each other;
a plurality of dummy bit lines, located on an outer side of the plurality of bit lines; the plurality of dummy bit lines at least include a first dummy bit line, a second dummy bit line and a third dummy bit line that are arranged spaced apart from each other along the horizontal direction in sequence, and bottoms of the first dummy bit line, the second dummy bit line, and the third dummy bit line are in direct contact with the insulating layer;
where the first dummy bit line is located on the second active area; the second dummy bit line and the third dummy bit line are located on the first active area; the first dummy bit line is directly adjacent to the second dummy bit line, the second dummy bit line is directly adjacent to the third dummy bit line, and the third dummy bit line is directly adjacent to the bit line.

In one embodiment, a width of the first dummy bit line in the horizontal direction is greater than a width of the second dummy bit line in the horizontal direction.

In one embodiment, the width of the second dummy bit line in the horizontal direction is greater than a width of the third dummy bit line in the horizontal direction.

In one embodiment, a first interval between the first dummy bit line and the second dummy bit line is smaller than a second interval between the second dummy bit line and the third dummy bit line.

In one embodiment, the semiconductor device may further include:
a plurality of contact structures between adjacent bit lines; a bottommost surface of the contact structure is lower than the topmost surface of the substrate.

In one embodiment, the contact structure may further be located between the first dummy bit line and the second dummy bit line and/or between the second dummy bit line and the third dummy bit line.

In one embodiment, the semiconductor device may further include:
at least one insulating structure between the first dummy bit line and the second dummy bit line and/or between the second dummy bit line and the third dummy bit line; a bottommost surface of the insulating structure is in direct contact with the insulating layer.

In one embodiment, the semiconductor device may further include:
a plurality of connecting pad structures, each of which is located on the contact structure or the insulating structure.

In one embodiment, the semiconductor device may further include:
a plurality of bit line sidewall structures, located on both sidewalls of the plurality of bit lines, the second dummy bit line and the third dummy bit line, and on a sidewall of the first dummy bit line close to the bit lines; the bit line sidewall structures have a first thickness.

In one embodiment, the semiconductor device may further include:
a gate structure, located on the substrate;
a gate spacer wall, located on a top surface and sidewalls of the gate structure, having a second thickness; the first thickness is smaller than the second thickness.

In one embodiment, the gate spacer wall may further extend and cover a sidewall of the first dummy bit line away from the bit lines.

In one embodiment, the semiconductor device may further include:
a plurality of isolation structures, located between the connecting pad structures, where a depth of an isolation structure in contact with the contact structure is greater than a depth of an isolation structure in contact with the insulating structure.

To solve the above technical problem, the second embodiment of the present application provides a semiconductor device, including:
a substrate;
a plurality of shallow trench isolations, arranged in the substrate and spaced apart from each other; the shallow trench isolations define a plurality of active areas;
an insulating layer, located on the substrate and the shallow trench isolations;
a plurality of bit lines, arranged on the substrate along a horizontal direction and spaced apart from each other;
a plurality of dummy bit lines, located on an outer side of the plurality of bit lines; the plurality of dummy bit lines at least include a first dummy bit line, a second dummy bit line and a third dummy bit line that are arranged spaced apart from each other along the horizontal direction in sequence; the first dummy bit line is directly adjacent to the second dummy bit line, the second dummy bit line is directly adjacent to the third dummy bit line, and the third dummy bit line is directly adjacent to the bit line; the first dummy bit line spans at least two active areas;
bit line sidewall structures, located on both sidewalls of the plurality of bit lines, the second dummy bit line and the third dummy bit line, and on a sidewall of the first dummy bit line close to the bit lines, and bottoms of the bit line sidewall structures located on the sidewalls of the dummy bit lines are higher than a top of the substrate and are located on the insulating layer.

In one embodiment, a width of the first dummy bit line in the horizontal direction is greater than a width of the second dummy bit line in the horizontal direction.

In one embodiment, the width of the second dummy bit line in the horizontal direction is greater than a width of the third dummy bit line in the horizontal direction.

In one embodiment, bottoms of the first dummy bit line, the second dummy bit line, and the third dummy bit line are in direct contact with the insulating layer.

In one embodiment, a first interval between the first dummy bit line and the second dummy bit line is smaller than the second interval between a second dummy bit line and the third dummy bit line.

To solve the above technical problem, in the third embodiment of the present application, a semiconductor device is provided, including:
a substrate;
an insulating layer;
a bit line group, including a plurality of first bit lines and a plurality of second bit lines that are arranged alternately; bottom surfaces of the plurality of first bit lines are lower than the topmost surface of the substrate; bottom surfaces of the plurality of second bit lines are higher than the topmost surface of the substrate and in contact with the insulating layer;
a plurality of dummy bit lines, located on an outer side of the bit line group; the plurality of dummy bit lines at least include a first dummy bit line, a second dummy bit line and a third dummy bit line that are arranged spaced apart from each other along a horizontal direction in sequence; and bottoms of the first dummy bit line, the second dummy bit line, and the third dummy bit line are in direct contact with the insulating layer;
where the first dummy bit line is directly adjacent to the second dummy bit line, the second dummy bit line is directly adjacent to the third dummy bit line, and the third dummy bit line is directly adjacent to the bit lines.

In one embodiment, a width of the first dummy bit line in the horizontal direction is greater than a width of the second dummy bit line in the horizontal direction, and the width of the second dummy bit line in the horizontal direction is greater than a width of the third dummy bit line in the horizontal direction.

In one embodiment, a first interval between the first dummy bit line and the second dummy bit line is smaller than a second interval between the second dummy bit line and the third dummy bit line.

In the present application, the semiconductor device includes a plurality of bit lines and a plurality of dummy bit lines, where the plurality of dummy bit lines are located on an outer side of the plurality of bit lines; and include a first dummy bit line, a second dummy bit line and a third dummy bit line that have different widths and intervals in the horizontal direction, such that a new structure for the semiconductor device is proposed, meanwhile the purpose of improving the performance and reliability of the semiconductor device is achieved.

### BRIEF DESCRIPTION OF THE DRAWINGS

FIGS. 1-9 are schematic structural diagrams of a semiconductor device during a manufacturing process according to an embodiment of the present application; where,

FIG. 1 is a schematic structural diagram of a semiconductor device according to an embodiment of the present application;

FIG. 2 is a schematic structural diagram of a semiconductor device according to an embodiment of the present application;

FIG. 3 is a schematic structural diagram of a semiconductor device according to an embodiment of the present application;

FIG. 4 is a schematic structural diagram of a semiconductor device according to an embodiment of the present application;

FIG. 5 is a schematic structural diagram of a semiconductor device according to the first embodiment of the present application;

FIG. 6 is a schematic structural diagram of a semiconductor device according to the second embodiment of the present application;

FIG. 7 is a schematic structural diagram of a semiconductor device according to the third embodiment of the present application;

FIG. 8 is a partial cross-sectional view of the semiconductor device taken along a line BB’ in FIG. 9;

FIG. 9 is a top view of the semiconductor device shown in FIG. 5.

Where, the reference signs are:

100-substrate, 100A- cell region, 100B- periphery region, 101- shallow trench isolation, AR- active area, AR1- first active area, AR2- second active area, D1- first width, D2- second width, 110- insulating layer, 120- bit line material layer, 121- semiconductor layer, 122- barrier layer, 123- metal layer, 124- cover layer, 121a- bit line contact plug, 251- gate structure, 131- gate spacer wall, 140- barrier layer, 151- third mask layer, 152- first mask layer, 153- second mask layer, 153a to 153f- mask patterns, 160- photoresist layer, H1- first interval, H2- second interval, H3- third interval, H4- fourth interval, H5- fifth interval, BL1- bit line, BL2- dummy bit line, BL2a- first dummy bit line, BL2b- second dummy bit line, BL2c- third dummy bit line, W1- width of the first dummy bit line in the horizontal direction, W2- width of the second dummy bit line in the horizontal direction, W3- width of the third dummy bit line in the horizontal direction, 170- bit line sidewall structure, 180- contact structure, 190- silicide layer, 201- connecting pad structure, 202- insulating structure, 210- isolation structure, WL- word line structure.

### DESCRIPTION OF THE EMBODIMENTS

The semiconductor device proposed by the present application will be described in further detail below in conjunction with the accompanying drawings and specific embodiments. According to the following description, the advantages and features of the present application will become clearer. It should be noted that the drawings are highly simplified and not drawn to exact scale, merely to facilitate and clearly assist in illustrating the purpose of the embodiments of the present application. In the following description, many specific details are described to facilitate a full understanding of the present application. However, the present application can also be implemented in other ways different from those described herein. Therefore, the present application is not limited by the specific embodiments disclosed below.

It should be noted that the drawings are highly simplified and not drawn to exact scale, merely to facilitate and clearly assist in illustrating the purpose of the embodiments of the present application. It is to be understood that the terms “on”, “over”, and “above” in the present application should be interpreted in the broadest manner, so that “on” not only means being “on” something with no intervening features or layers therebetween (i.e., directly on something), but also includes being “on” something with intervening features or layers therebetween. In the embodiments of the present application, terms such as “first”, “second”, etc. are used to distinguish similar objects and are not necessarily used to describe a specific order or sequence. Moreover, the technical solutions recorded in the embodiments of the present application can be combined arbitrarily without conflict.

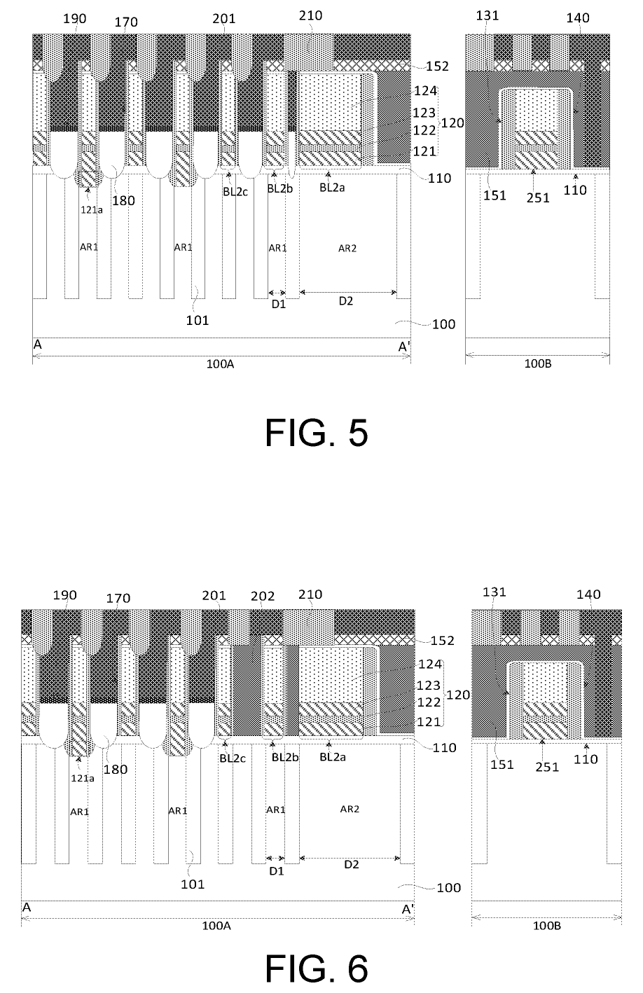

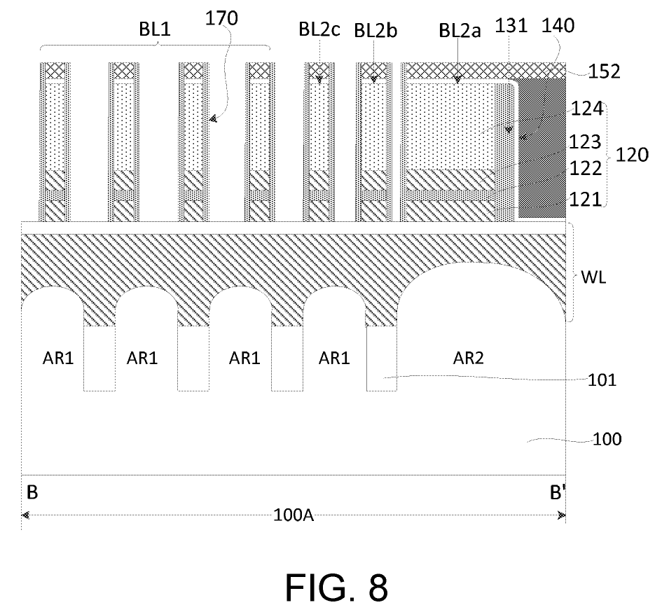

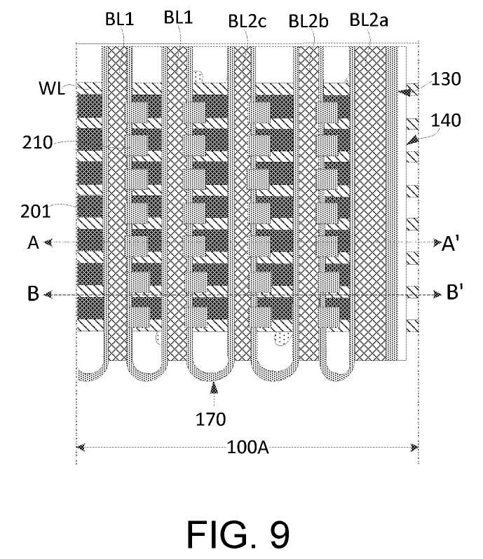

Please refer to FIG. 5 in combination with FIGS. 8 and 9, where FIG. 9 is a top view of the semiconductor device shown in FIG. 5. FIG. 8 is a partial cross-sectional view of the semiconductor device taken along a line BB’ in FIG. 9 according to the first embodiment of the present application. FIG. 5 is a partial cross-sectional view of the semiconductor device taken along a line AA’ in FIG. 9 according to the first embodiment of the present application. The semiconductor device of the present application can be used to manufacture dynamic random access memory (DRAM). Without departing from the spirit of the present application, the present application can also be applied to other types of memory.

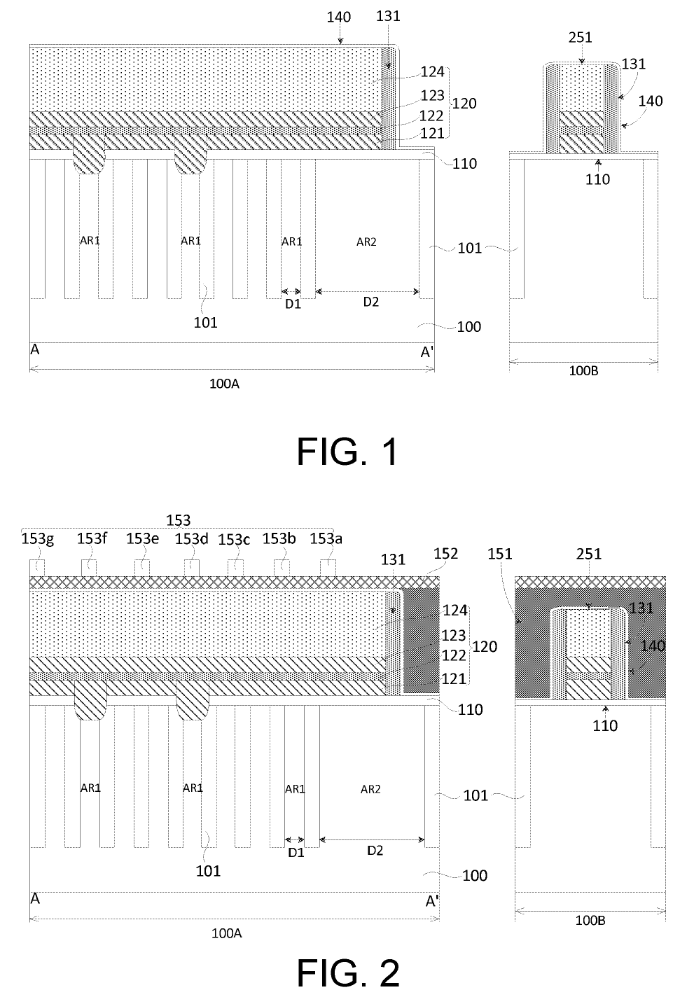

As shown in FIG. 5, the semiconductor device in the first embodiment of the present application includes a substrate 100, a plurality of bit lines BL1, and a plurality of dummy bit lines BL2. Specifically, the substrate 100 may include a cell region 100A and a periphery region 100B. Where, the cell region 100A is, for example, a cell region of a semiconductor device having relatively high component density. The periphery region 100B is, for example, a periphery region of a semiconductor device having relatively low component density. The cell region 100A and the periphery region 100B are, for example, arranged adjacent to each other. However, to clearly show the structures of corresponding components on different regions (cell region 100A and periphery region 100B) in the embodiment of the present application, FIGS. 1-7 of the embodiment of the present application depict the cell region 100A and the periphery region 100B and their corresponding structures respectively, and a word line structure WL is not shown due to the location of cross-section lines. Moreover, a plurality of shallow trench isolations (STI) 101 are arranged in the cell region 100A and the periphery region 100B of the substrate 100 to define a plurality of active areas AR in the substrate 100. The active areas AR can be specifically divided into a plurality of first active areas AR1 and at least one second active area AR2 based on the width of the substrate 100 in a direction parallel to the surface of the substrate 100 (hereinafter simply referred to as the horizontal direction). The second active area AR2 can be arranged on the outer side of all the first active areas AR1. For example, as shown in FIG. 5, a plurality of first active areas AR1 and one second active area AR2 can be arranged sequentially from left to right. If a width of the first active area AR1 in the horizontal direction is defined as a first width D1, and a width of the second active area AR2 in the horizontal direction is defined as a second width D2, the first width D1 of the first active area AR1 can be smaller than the second width D2 of the second active area AR2 (D1<D2), but not limited thereto.

In one embodiment, the substrate 100 is any suitable substrate material known in the art, for example, a silicon substrate, a silicon-containing substrate (such as SiC, SiGe) or a silicon-on-insulator substrate, or a substrate composed of other suitable materials, but not limited thereto. The shallow trench isolations 101 may include a single-layer or multi-layer dielectric material. Applicable dielectric materials may include, for example, silicon oxide (SiO₂), silicon nitride (SiN), silicon oxynitride (SiON), silicon carbonitride (SiCN), nitrogen-doped silicon carbide (NDC), low dielectric constant (low‑k) dielectric materials such as fluorinated silica glass (FSG), silicon oxycarbide (SiCOH), spin-on glass, porous low-k dielectric material, organic polymer dielectric material, or combinations of the aforementioned materials, but not limited thereto. Exemplarily, the shallow trench isolations 101 in this embodiment may be strip-shaped with their long axes extending along a direction perpendicular to the surface of the substrate 100 (hereinafter simply referred to as the vertical direction). In addition, an insulating layer 110 is further arranged on the surface of the substrate 100. The thickness of the insulating layer 110 in the vertical direction may be different on the cell region 100A and the periphery region 100B of the substrate 100. For example, the thickness of the insulating layer 110 on the periphery region 100B is less than the thickness of the insulating layer 110 on the cell region 100A. Specifically, the insulating layer 110 may be a single-layer structure, such as a silicon oxide layer or a silicon nitride layer, or may be a composite layer, such as an ONO composite layer composed of a silicon oxide layer, a silicon nitride layer, and a silicon oxide layer, but not limited thereto.

Referring also to FIG. 4, the plurality of bit lines BL1 in the first embodiment of the present application may be arranged on the substrate 100 spaced apart from each other along the horizontal direction from left to right, and some of the bit lines BL1 have bit line contact plugs 121a located below the bit lines BL1 and extending vertically into the substrate 100. The plurality of dummy bit lines BL2 may be arranged spaced apart from each other along the horizontal direction on one side of the plurality of bit lines BL1, for example, on the right side of the plurality of bit lines BL1 as shown in FIGS. 4 or 5. Exemplarily, the plurality of dummy bit lines BL2 can be divided into at least one first dummy bit line BL2a, at least one second dummy bit line BL2b, and at least one third dummy bit line BL2c. The first dummy bit line BL2a is directly adjacent to the second dummy bit line BL2b, the second dummy bit line BL2b is directly adjacent to the third dummy bit line BL2c, and the third dummy bit line BL2c is directly adjacent to the bit line BL1, thereby forming the plurality of dummy bit lines BL2 arranged sequentially from right to left in the horizontal direction as shown in FIG. 4. It should be particularly noted that the plurality of dummy bit lines BL2 in the first embodiment of the present application are all located on the insulating layer 110, that is, the bottoms of the plurality of dummy bit lines BL2 are in direct contact with the top surface of the insulating layer 110. In detail, the first dummy bit line BL2a is specifically located on the insulating layer 110 over the second active area AR2, while the second dummy bit line BL2b and the third dummy bit line BL2c are specifically located on the insulating layer 110 over the first active areas AR1. Moreover, the widths of the plurality of dummy bit lines BL2 in the horizontal direction and the intervals between adjacent ones may be different. For example, the width W1 of the first dummy bit line BL2a in the horizontal direction is greater than the width (W2, W3) of the second dummy bit line BL2b or the third dummy bit line BL2c in the horizontal direction, and the width W2 of the second dummy bit line BL2b in the horizontal direction is greater than the width W3 of the third dummy bit line BL2c in the horizontal direction. The first interval H1 between the first dummy bit line BL2a and the second dummy bit line BL2b is smaller than the second interval H2 between the second dummy bit line BL2b and the third dummy bit line BL2c, but the second interval H2 between the second dummy bit line BL2b and the third dummy bit line BL2c is equal to the third interval H3 between the third dummy bit line BL2c and the bit line BL1 adjacent thereto (the bit line BL1 on the left side of the third dummy bit line BL2c), i.e., 0<H1<H2=H3, but not limited thereto.

It should be understood that in other embodiments, based on whether bit line contact plugs 121a are formed below the bit lines BL1 or the positional relationship between the bottom surfaces of the bit lines and the substrate 100, the bit lines BL1 are named as a bit line group; the bit line BL1, the bottom surface of which is lower than the topmost surface of the substrate 100 or under which a bit line contact plug 121a is disposed, is named as the first bit line; the bit line BL1, the bottom surface of which is higher than the topmost surface of the substrate 100 and is in contact with the insulating layer 110 or under which no bit line contact plug 121a is disposed, is named as the second bit line. To simplify the description, the two are combined and explained below, for example, as a plurality of bit lines BL1 (bit line group), and the bit lines BL1 (bit line group) are simply referred to as bit lines BL1, but not limited thereto.

In one embodiment, each of the plurality of bit lines BL1 and the plurality of dummy bit lines BL2 may have the same multi-layer bit line material layer 120 including such as a semiconductor layer 121, a barrier layer 122, a metal layer 123, and a cover layer 124 that are stacked sequentially from bottom to top. Where, the material of the semiconductor layer 121 may include crystalline silicon, polycrystalline silicon, amorphous silicon, doped silicon, silicon germanium (SiGe), or other suitable semiconductor materials, but not limited thereto. The material of the barrier layer 122 may include a metal, a metallic silicide, or a metallic nitride, such as titanium (Ti), titanium nitride (TiN), tungsten silicide (WSi), cobalt silicide (CoSi), tungsten nitride (WN), but not limited thereto. The material of the metal layer 123 may include tungsten (W), copper (Cu), aluminum (Al), titanium (Ti), tantalum (Ta), or compounds, alloys, and/or composite layers of the aforementioned metal materials, but not limited thereto. The cover layer 124 may include a dielectric material, such as silicon oxide (SiO₂), silicon nitride (SiN), silicon oxynitride (SiON), silicon carbonitride (SiCN), or combinations of the aforementioned materials, but not limited thereto. Exemplarily, the material of the semiconductor layer 121 is polycrystalline silicon, the material of the barrier layer 122 is cobalt silicide (CoSi), the material of the metal layer 123 is tungsten (W), and the material of the cover layer 124 is silicon nitride (SiN).

It should be understood that during the process of forming the plurality of bit lines BL1 and the plurality of dummy bit lines BL2, at least one gate structure 251 is also synchronously formed correspondingly on the periphery region 100B of the substrate 100. Since the thickness of the insulating layer 110 in the periphery region 100B may be less than the thickness of the insulating layer 110 in the cell region 100A, the top surface of the gate structure 251 may also be lower than the top surfaces of the plurality of bit lines BL1 and the plurality of dummy bit lines BL2 in the cell region 100A, but not limited thereto.

Continuing to refer to FIG. 5, sidewall structures are also arranged on the sidewalls of the plurality of bit lines BL1 and the plurality of dummy bit lines BL2 in the first embodiment of the present application. For ease of distinction, in the present application the sidewall structures, which are formed on both sidewalls of the plurality of bit lines BL1, the third dummy bit line BL2c and the second dummy bit line BL2b, and on one sidewall of the first dummy bit line BL2a, are referred to as bit line sidewall structures 170; and the sidewall structures, which are located on the other sidewall of the first dummy bit line BL2a and on both sidewalls of the gate structure 251 on the periphery region 100B, are referred to as gate spacer walls 131. In one embodiment, each of the bit line sidewall structure 170 and the gate spacer wall 131 may include a single-layer or multi-layer insulating material, such as silicon oxide, silicon nitride, silicon carbonitride, or combinations of the aforementioned materials. The thicknesses of the bit line sidewall structure 170 and the gate spacer wall 131 in the horizontal direction may be different. For example, the thickness of the bit line sidewall structure 170 in the horizontal direction is smaller than the thickness of the gate spacer wall 131 in the horizontal direction, but not limited thereto.

Furthermore, in the first embodiment of the present application, a barrier layer 140 is further arranged on the top surfaces of the plurality of bit lines BL1 and the plurality of dummy bit lines BL2, as well as on the top surface of the gate structure 251 and the outer surfaces of its gate spacer walls 131 and on the insulating layer 110 exposed on both sides of the gate structure 251. A first mask layer 152 (for example, the material is a nitride) is further formed on the barrier layer 140 (for example, the material is an oxide) on the top surfaces of the plurality of bit lines BL1 and the plurality of dummy bit lines BL2. Since the top surface of the gate structure 251 in the periphery region 100B is lower than the top surfaces of the plurality of bit lines BL1 and the plurality of dummy bit lines BL2 in the cell region 100A, the top surfaces of the barrier layer 140 and the first mask layer 152 in the periphery region 100B are correspondingly also lower than the top surfaces of the barrier layer 140 and the first mask layer 152 in the cell region 100A, but not limited thereto.

Continuing to refer to FIG. 5, the semiconductor device in the first embodiment of the present application further includes a plurality of contact structures 180. The plurality of contact structures 180 can be respectively arranged in the intervals between adjacent bit lines BL1 (the first bit lines and second bit lines in the bit line group), between adjacent bit line BL1 and dummy bit line BL2, and between adjacent dummy bit lines BL2. However, based on the different widths of the intervals, the widths of the plurality of contact structures 180 in the horizontal direction may be different. For example, the widths of the contact structures 180 between adjacent bit lines BL1 in the horizontal direction may be the same, but the width of the contact structure 180 between the adjacent bit line BL1 and the third dummy bit line BL2c in the horizontal direction may be greater than the width of the contact structure 180 between the adjacent second dummy bit line BL2b and the first dummy bit line BL2a in the horizontal direction. The width of the contact structure 180 between the third dummy bit line BL2c and the second dummy bit line BL2b in the horizontal direction may be equal to the width of the contact structure 180 between the adjacent bit line BL1 and the third dummy bit line BL2c in the horizontal direction, but not limited thereto. In one embodiment, both sides of the contact structure 180 are separated from and not direct contact with the bit line BL1 and the dummy bit line BL2 by the bit line sidewall structures 170, and the contact structures 180 extend vertically in the substrate 100 between adjacent bit lines BL1 and dummy bit lines BL2 along a direction perpendicular to the surface of the substrate 100, to be electrically connected to the substrate 100. In one embodiment, the material of the contact structure 180 may include crystalline silicon, polycrystalline silicon, amorphous silicon, doped silicon, silicon germanium (SiGe), or other suitable silicon-containing semiconductor materials, but not limited thereto. Exemplarily, the material of the contact structure 180 is phosphorus-doped silicon (SiP).

Furthermore, in this embodiment, a silicide layer 190 and a connecting pad structure 201 conformally covering the silicide layer 190, the bit line sidewall structure 170, and the first mask layer 152, as well as an isolation structure 210 between adjacent connecting pad structures 201 are further arranged on the contact structure 180. In one embodiment, the connecting pad structure 201 may be a single-layer structure, as shown in FIG. 5, and in this case, its material may be tungsten (W), copper (Cu), aluminum (Al), titanium (Ti), tantalum (Ta), nitrides, silicides, alloys, and/or composite layers of the aforementioned materials, and in one embodiment, the material is tungsten (W). The material of the connecting pad structure 201 may also be a multi-layer composite structure (not shown), and in this case, its material may be a stacking structure of a conductive barrier material (in one embodiment, the material is titanium nitride) such as titanium and/or titanium nitride (TiN), tantalum (Ta) and/or tantalum nitride (TaN), etc., and tungsten (W), copper (Cu), aluminum (Al), titanium (Ti), tantalum (Ta), a nitride, a silicide, an alloy, and/or a composite layer (in one embodiment, the material is tungsten W) of the aforementioned materials, but not limited thereto. The material of the isolation structure 210 may include a nitride, such as silicon nitride, or may include an oxide, such as silicon oxide, and in one embodiment, the material is silicon nitride, but not limited thereto.

It should be understood that the shapes of some of a plurality of isolation structures 210 in this embodiment may be different. For example, since the gap between the second dummy bit line BL2b and the first dummy bit line BL2a has a smaller width in the horizontal direction, the bottom surface of the isolation structure 210 in the connecting pad structure 201 between the second dummy bit line BL2b and the first dummy bit line BL2a is higher than the bottom surface of the isolation structure 210 in the connecting pad structure 201 between adjacent bit lines BL1, or higher than the bottom surfaces of the isolation structures 210 in the connecting pad structures 201 between other dummy bit lines BL2, but not limited thereto.

It should be understood that the term “conformally” in the embodiments of the present application refers to constructing a continuous structural shape by utilizing the similarity and correlation in morphology between two or more forms.

Those skilled in the art of the present application should readily understand that, under the premise of meeting actual product requirements, the semiconductor device of the present application may also have other forms and is not limited to the above. Other embodiments or variations of the semiconductor device of the present application will be further described below. For simplicity of description, the same components in the embodiments of the present application are labeled with the same reference signs to facilitate cross-reference between the embodiments.

Please refer to FIG. 6, which is a schematic structural diagram of a semiconductor device according to a second embodiment of the present application. As shown in FIG. 6, the structure of the semiconductor device in the second embodiment of the present application is substantially the same as that of the semiconductor device in the aforementioned first embodiment. For example, the semiconductor device also includes a substrate 100, a plurality of first active areas AR1, at least one second active area AR2, a plurality of bit lines BL1 (bit line group), a plurality of dummy bit lines BL2, bit line sidewall structures 170, a gate structure 251, gate spacer walls 131, a barrier layer 140, etc. The same parts will not be repeated here. The main difference between the semiconductor device in the second embodiment of the present application and the aforementioned first embodiment is that: the semiconductor device further includes a plurality of insulating structures 202, and the insulating structures 202 are specifically located in the gaps between the third dummy bit line BL2c and the second dummy bit line BL2b, and between the second dummy bit line BL2b and the first dummy bit line BL2a. That is, the plurality of contact structures 180 in the second embodiment of the present application are specifically located between the plurality of bit lines BL1 (bit line group), between the bit line BL1 and the third dummy bit line BL2c, while the gaps between the third dummy bit line BL2c and the second dummy bit line BL2b, and between the second dummy bit line BL2b and the first dummy bit line BL2a do not have contact structures 180 and silicide layers 190. Moreover, some of the isolation structures 210 in the second embodiment of the present application are also different from some of the isolation structures 210 in the aforementioned first embodiment. For example, in this embodiment, the bottom surfaces of the isolation structures 210 in the connecting pad structures 201 in the gaps between the third dummy bit line BL2c and the second dummy bit line BL2b, and between the second dummy bit line BL2b and the first dummy bit line BL2a are all higher than the bottom surface of the isolation structure 210 in the connecting pad structure 201 between adjacent bit lines BL1. In one embodiment, the material of the insulating structure 202 may be an oxide or a nitride, such as silicon dioxide or silicon nitride, but not limited thereto.

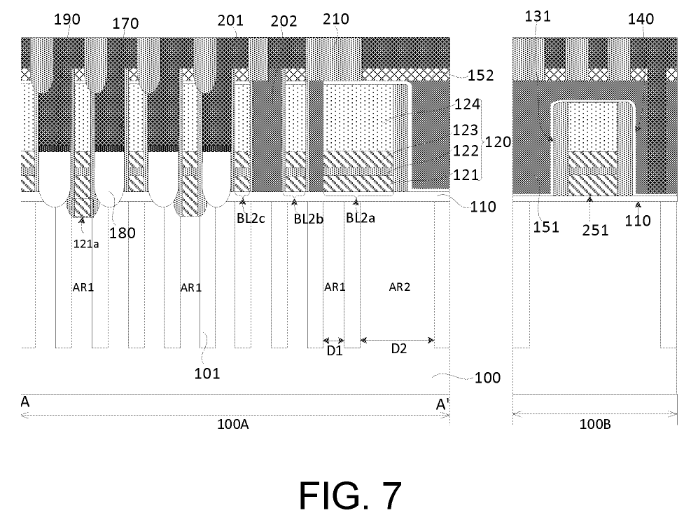

Please refer to FIG. 7, which is a schematic structural diagram of a semiconductor device according to a third embodiment of the present application. As shown in FIG. 7, the structure of the semiconductor device in the third embodiment of the present application is substantially the same as that of the semiconductor device in the aforementioned second embodiment. For example, the semiconductor device also includes a substrate 100, the substrate 100 includes a plurality of first active areas AR1 and at least one second active area AR2, a plurality of bit lines BL1 (bit line group), a plurality of dummy bit lines BL2, bit line sidewall structures 170, a gate structure 251, gate spacer walls 131, a barrier layer 140, a plurality of contact structures 180, a plurality of insulating structures 202, a plurality of isolation structures 210, etc. Where, the gaps between the third dummy bit line BL2c and the second dummy bit line BL2b, and between the second dummy bit line BL2b and the first dummy bit line BL2a do not have contact structures 180 and silicide layers 190, but have insulating structures 202. The same parts will not be repeated here. The main difference between the semiconductor device in the third embodiment of the present application and the aforementioned second embodiment is that: the first dummy bit line BL2a among the plurality of dummy bit lines BL2 is specifically located on the insulating layer 110 over the first active area AR1 and the second active area AR2, i.e., the first dummy bit line BL2a spans two active areas.

To enable those skilled in the art of the present application to readily understand the semiconductor device in the embodiments of the present application, the present application also provides a manufacturing method for the semiconductor device. The manufacturing method of the semiconductor device proposed by the present application will be further described below in conjunction with schematic diagrams of structures at various stages of the manufacturing process.

Where, FIGS. 1-5 are schematic structural diagrams during the manufacturing process of a semiconductor device according to the first embodiment of the present application.

Please refer to FIG. 1 in combination it with FIG. 5. Firstly, a substrate 100 (for example, the material is a silicon substrate) is provided. The substrate 100 includes a cell region 100A and a periphery region 100B. Then, a plurality of trenches (not shown) are formed in both the cell region 100A and the periphery region 100B of the substrate 100 by using an etching method. An insulating material (for example, the material is silicon oxide or silicon oxynitride) is then filled into the trenches to form a plurality of shallow trench isolations 101 and a plurality of active areas AR defined by the shallow trench isolations 101 in the substrate 100. Exemplarily, the shallow trench isolations 101 may be strip-shaped extending along the vertical direction, and the plurality of shallow trench isolations 101 can divide the active areas AR into a plurality of first active areas AR1 and at least one second active area AR2. The second active area AR2 may be arranged on the outer side of all the first active areas AR1, and the first width D1 of the first active area AR1 may be smaller than the second width D2 of the second active area AR2 (D1<D2), but not limited thereto.

Then, an insulating layer 110 can be formed on the surface of the substrate 100 by using a deposition process such as at least one of physical vapor deposition, chemical vapor deposition, atomic layer deposition, etc. Then, a plurality of bit line contact plug holes (not shown) are formed in the insulating layer 110 and the substrate 100. The bit line contact plug holes are the corresponding positions in the substrate 100 for subsequently forming the bit line contact plugs 121a. Then, a material layer (for example, the material is polycrystalline silicon) for the bit line contact plugs 121a can be formed in the bit line contact plug holes using the aforementioned deposition processes. Then, a bit line material layer 120 composed of a semiconductor layer 121 (for example, the material is polycrystalline silicon), a barrier layer 122 (for example, the material is titanium nitride), a metal layer 123 (for example, the material is tungsten), and a cover layer 124 (for example, the material is silicon nitride) that are stacked sequentially from bottom to top is formed on most regions of the substrate 100 and on the material layer of the bit line contact plugs 121a. Gate spacer walls 131 (for example, the material is silicon nitride) are formed on sidewalls of the bit line material layer 120 near the exposed surface of the substrate 100, and a barrier layer 140 (for example, the material is silicon dioxide) is conformally formed to cover the bit line material layer 120, the gate spacer walls 131, and the exposed surface of the substrate 100. It should be understood that the gate structure 251 in the periphery region 100B of the semiconductor device is formed before the plurality of bit lines BL1 (bit line group) and dummy bit lines BL2 in the cell region 100A. Therefore, the gate structure 251 shown in FIG. 1 is a discrete structure.

Please refer to FIG. 2 in combination with FIG. 5. A third mask layer 151 and a first mask layer 152 are sequentially formed on the barrier layer 140 on the both cell region 100A and the periphery region 100B of the substrate 100 by using a deposition process such as chemical vapor deposition. At this time, the top surfaces of the third mask layer 151 and the first mask layer 152 in the periphery region 100B and the cell region 100A are correspondingly flush (at the same horizontal height). Then, a second mask layer 153 is formed on the first mask layer 152 on the cell region 100A. The second mask layer 153 includes mask patterns arranged spaced apart from each other along the horizontal direction, for example, from right to left, a first mask pattern 153a to a seventh mask pattern 153g are arranged in sequence. The gaps between some adjacent mask patterns in the second mask layer 153 may be the same. For example, the gap between the seventh mask pattern 153g and the sixth mask pattern 153f is the same as the gap between the sixth mask pattern 153f and the fifth mask pattern 153e. The gaps between some adjacent mask patterns may be different. For example, the gap between the fourth mask pattern 153d and the third mask pattern 153c is different. These are prepared for forming the plurality of bit lines BL1 (bit line group) and the plurality of dummy bit lines BL2. In another embodiment (not shown), the gaps between the first mask pattern 153a to the seventh mask pattern 153g are all the same, but not limited thereto. Exemplarily, if the gap between the fourth mask pattern 153d and the third mask pattern 153c is a sixth gap H6, the gap between the third mask pattern 153c and the second mask pattern 153b is a fifth gap H5, and the gap between the second mask pattern 153b and a photoresist layer 160 adjacent thereto is a fourth gap H4, then H6>H5>H4.

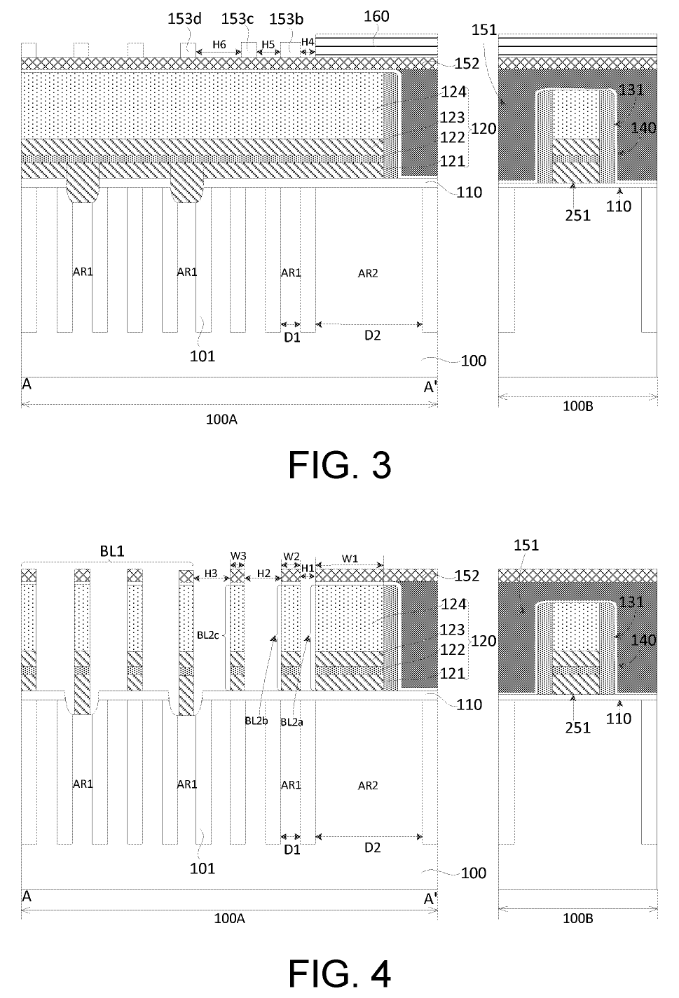

Please refer to FIG. 3 in combination with FIG. 5. Then, a photoresist layer 160 is formed in both the periphery region 100B and the cell region 100A of the substrate 100. Specifically, the photoresist layer 160 covers the third mask layer 151 on the periphery region 100B and the top surfaces of part of the first mask layer 152 and part of the second mask layer 153 on the cell region 100A, and exposes part of the second mask layer 152 and the third mask layer 151. That is, for the cell region 100A of the substrate 100, the photoresist layer 160 shields the first mask pattern 153a located at the rightmost in the horizontal direction in the second mask layer 153, part of the gap between the first mask pattern 153a and the second mask pattern 153b, and the first mask layer 152 on the right side of the first mask pattern 153a, thereby achieving the formation of the first dummy bit line BL2a, the second dummy bit line BL2b, and the third dummy bit line BL2c with different intervals and widths between them by adjusting the gap between the first mask pattern 153a and the second mask pattern 153b by means of the photoresist layer 160.

Please refer to FIG. 4 in combination with FIG. 5. Then, the plurality of mask patterns in the second mask layer 153 are used as a mask, part of the barrier layer 140, part of the bit line material layer 120, part of the insulating layer 110, and part of the substrate 100 are etched and removed along the vertical direction to form the plurality of bit lines BL1 (bit line group) and the plurality of dummy bit lines BL2 arranged spaced apart from each other along the horizontal direction on the substrate 100. The plurality of dummy bit lines BL2 can be divided into at least one first dummy bit line BL2a, at least one second dummy bit line BL2b, and at least one third dummy bit line BL2c. The first dummy bit line BL2a is directly adjacent to the second dummy bit line BL2b, the second dummy bit line BL2b is directly adjacent to the third dummy bit line BL2c, and the third dummy bit line BL2c is directly adjacent to the bit line BL1 (first bit line). It should be understood that during the process of forming the plurality of bit lines BL1 (bit line group) and the plurality of dummy bit lines BL2, at least one gate structure 251 is also synchronously formed correspondingly on the periphery region 100B of the substrate 100. Since the thickness of the insulating layer 110 in the periphery region 100B may be less than the thickness of the insulating layer 110 in the cell region 100A, and therefore, the top surface of the gate structure 251 is also lower than the top surfaces of the plurality of bit lines BL1 and the plurality of dummy bit lines BL2 in the cell region 100A, but not limited thereto.

Please refer to FIG. 5. Then, corresponding sidewall structures can be formed on the sidewalls of the plurality of bit lines BL1 (bit line group) and the plurality of dummy bit lines BL2 by using a deposition process, for example, the bit line sidewall structures 170 (for example, the material is silicon dioxide) are formed on both sidewalls of the plurality of bit lines BL1, the third dummy bit line BL2c, the second dummy bit line BL2b, and on one sidewall of the first dummy bit line BL2a, and the gate spacer walls 131 (for example, the material is silicon dioxide) are formed on the other sidewall of the first dummy bit line BL2a and on both sidewalls of the gate structure 251 on the periphery region 100B. In one embodiment, the thicknesses of the bit line sidewall structure 170 and the gate spacer wall 131 in the horizontal direction may be different. For example, the thickness of the bit line sidewall structure 170 in the horizontal direction is smaller than the thickness of the gate spacer wall 131 in the horizontal direction, but not limited thereto. Then, contact structures 180 (for example, the material is phosphorus-doped silicon), silicide layers 190, connecting pad structures 201 (for example, the material is a metal, copper), and isolation structures 210 (for example, the material is an insulating material, silicon nitride) between adjacent connecting pad structures 201 are further sequentially formed in the intervals between adjacent bit lines BL1 (first bit line and second bit line in the bit line group), between adjacent bit line BL1 (first bit line) and dummy bit line BL2, and between adjacent dummy bit lines BL2 by further using a deposition process, photolithography, and etching process.

To enable those skilled in the art of the present application to readily understand the semiconductor device in the second or third embodiment of the present application, the present application also provides a manufacturing method for the semiconductor device. The manufacturing method of the semiconductor device proposed by the present application will be further described below in conjunction with schematic diagrams of structures at various stages of the manufacturing process.

FIGS. 1-4 and 5 or 6 are schematic structural diagrams during the manufacturing process of a semiconductor device according to a second or third embodiment of the present application. Since the semiconductor devices in the second or third embodiments of the present application are substantially the same as the aforementioned first embodiment, the manufacturing methods for their corresponding components and/or devices are also the same. The parts of the manufacturing method for the second or third embodiment that are the same as the manufacturing method for the aforementioned first embodiment will not be repeated below, and only the different manufacturing processes between them will be explained.

Specifically, as shown in FIG. 6, when forming the semiconductor device in the second embodiment of the present application, before the contact structures 180, silicide layers 190, and connecting pad structures 201 in the gaps between adjacent bit lines BL1 and in the gap between the bit line BL1 and the third dummy bit line BL2c are formed, insulating structures 202 (for example, the material is silicon dioxide or silicon nitride) can be further formed in the gaps between the third dummy bit line BL2c and the second dummy bit line BL2b, and between the second dummy bit line BL2b and the first dummy bit line BL2a by using a deposition process. In the formation of the semiconductor device in the third embodiment of the present application, the step of forming the plurality of shallow trench isolations 101 in the substrate 100 is different from that in the aforementioned first embodiment. Specifically, one more shallow trench isolation 101 can be formed in the substrate 100 so as to make the subsequently formed first dummy bit line BL2a span two active areas, i.e., first active area AR1 and second active area AR2.

In summary, the semiconductor device in the present application includes a plurality of bit lines and a plurality of dummy bit lines, where the plurality of dummy bit lines are located on an outer side of the plurality of bit lines; and include a first dummy bit line, a second dummy bit line, and a third dummy bit line that have different widths and intervals in the horizontal direction, such that a new structure for the semiconductor device is proposed, meanwhile the purpose of improving the performance and reliability of the semiconductor device is achieved.

The above descriptions are merely preferred embodiments of the present application and are not intended to limit the protection scope of the present application. Any modifications, equivalent replacements, improvements, etc. made within the spirit and principles of the present application shall be included within the protection scope of the present application.

What is claimed is:

1. A semiconductor device, comprising:
a substrate;
a plurality of shallow trench isolations, arranged in the substrate and spaced apart from each other; the shallow trench isolations define a plurality of active areas, comprising a plurality of first active areas having a first width and at least one second active area having a second width; the at least one second active area is arranged on an outer side of all the first active areas, and the first width is smaller than the second width;
an insulating layer, located on the substrate and the shallow trench isolations;
a plurality of bit lines, arranged on the substrate along a horizontal direction and spaced apart from each other;
a plurality of dummy bit lines, located on an outer side of the plurality of bit lines; the plurality of dummy bit lines at least comprise a first dummy bit line, a second dummy bit line and a third dummy bit line that are arranged spaced apart from each other along the horizontal direction in sequence, and bottoms of the first dummy bit line, the second dummy bit line, and the third dummy bit line are in direct contact with the insulating layer;
wherein the first dummy bit line is located on the second active area; the second dummy bit line and the third dummy bit line are located on the first active area; the first dummy bit line is directly adjacent to the second dummy bit line, the second dummy bit line is directly adjacent to the third dummy bit line, and the third dummy bit line is directly adjacent to the bit line.

2. The semiconductor device according to claim 1, wherein a width of the first dummy bit line in the horizontal direction is greater than a width of the second dummy bit line in the horizontal direction.

3. The semiconductor device according to claim 1, wherein the width of the second dummy bit line in the horizontal direction is greater than a width of the third dummy bit line in the horizontal direction.

4. The semiconductor device according to claim 1, wherein a first interval between the first dummy bit line and the second dummy bit line is smaller than a second interval between the second dummy bit line and the third dummy bit line.

5. The semiconductor device according to claim 1, further comprising:
a plurality of contact structures between adjacent bit lines; a bottommost surface of the contact structure is lower than a topmost surface of the substrate.

6. The semiconductor device according to claim 5, wherein the contact structure is located between the first dummy bit line and the second dummy bit line and/or between the second dummy bit line and the third dummy bit line.

7. The semiconductor device according to claim 1, further comprising:
at least one insulating structure between the first dummy bit line and the second dummy bit line and/or between the second dummy bit line and the third dummy bit line; a bottommost surface of the insulating structure is in direct contact with the insulating layer.

8. The semiconductor device according to claim 7, further comprising:
a plurality of connecting pad structures, each of which is located on the contact structure or the insulating structure.

9. The semiconductor device according to claim 1, further comprising:
a plurality of bit line sidewall structures, located on both sidewalls of the plurality of bit lines, the second dummy bit line and the third dummy bit line, and on a sidewall of the first dummy bit line close to the bit lines; the bit line sidewall structures have a first thickness.

10. The semiconductor device according to claim 1, further comprising:
a gate structure, located on the substrate;
a gate spacer wall, located on a top surface and sidewalls of the gate structure, having a second thickness; the first thickness is smaller than the second thickness.

11. The semiconductor device according to claim 10, wherein the gate spacer wall extends and cover a sidewall of the first dummy bit line away from the bit lines.

12. The semiconductor device according to claim 8, further comprising:
a plurality of isolation structures, located between the connecting pad structures, wherein a depth of an isolation structure in contact with the contact structure is greater than a depth of an isolation structure in contact with the insulating structure.

13. A semiconductor device, comprising:
a substrate;
a plurality of shallow trench isolations, arranged in the substrate and spaced apart from each other; the shallow trench isolations define a plurality of active areas;
an insulating layer, located on the substrate and the shallow trench isolations;
a plurality of bit lines, arranged on the substrate along a horizontal direction and spaced apart from each other;
a plurality of dummy bit lines, located on an outer side of the plurality of bit lines; the plurality of dummy bit lines at least comprise a first dummy bit line, a second dummy bit line and a third dummy bit line that are arranged spaced apart from each other along the horizontal direction in sequence; the first dummy bit line is directly adjacent to the second dummy bit line, the second dummy bit line is directly adjacent to the third dummy bit line, and the third dummy bit line is directly adjacent to the bit line; the first dummy bit line spans at least two active areas;
bit line sidewall structures, located on both sidewalls of the plurality of bit lines, the second dummy bit line and the third dummy bit line, and on a sidewall of the first dummy bit line close to the bit lines, and bottoms of the bit line sidewall structures located on the sidewalls of the dummy bit lines are higher than a top of the substrate and are located on the insulating layer.

14. The semiconductor device according to claim 13, wherein a width of the first dummy bit line in the horizontal direction is greater than a width of the second dummy bit line in the horizontal direction.

15. The semiconductor device according to claim 13, wherein the width of the second dummy bit line in the horizontal direction is greater than a width of the third dummy bit line in the horizontal direction.

16. The semiconductor device according to claim 13, wherein bottoms of the first dummy bit line, the second dummy bit line, and the third dummy bit line are in direct contact with the insulating layer.

17. The semiconductor device according to claim 13, wherein a first interval between the first dummy bit line and the second dummy bit line is smaller than a second interval between the second dummy bit line and the third dummy bit line.

18. A semiconductor device, comprising:
a substrate;
an insulating layer;
a bit line group, comprising a plurality of first bit lines and a plurality of second bit lines that are arranged alternately; bottom surfaces of the plurality of first bit lines are lower than a topmost surface of the substrate; bottom surfaces of the plurality of second bit lines are higher than the topmost surface of the substrate and in contact with the insulating layer;
a plurality of dummy bit lines, located on an outer side of the bit line group; the plurality of dummy bit lines at least comprise a first dummy bit line, a second dummy bit line and a third dummy bit line that are arranged spaced apart from each other along a horizontal direction in sequence; and bottoms of the first dummy bit line, the second dummy bit line, and the third dummy bit line are in direct contact with the insulating layer;
wherein the first dummy bit line is directly adjacent to the second dummy bit line, the second dummy bit line is directly adjacent to the third dummy bit line, and the third dummy bit line is directly adjacent to the bit lines.

19. The semiconductor device according to claim 18, wherein a width of the first dummy bit line in the horizontal direction is greater than a width of the second dummy bit line in the horizontal direction, and the width of the second dummy bit line in the horizontal direction is greater than a width of the third dummy bit line in the horizontal direction.

20. The semiconductor device according to claim 18, wherein a first interval between the first dummy bit line and the second dummy bit line is smaller than a second interval between the second dummy bit line and the third dummy bit line.
